(19) United States
(12) Patent Application Publication
(10) Pub. No.: US 2026/0026295 A1
(43) Pub. Date: Jan. 22, 2026

(54) UNIVERSAL CALIBRATION SYSTEM FOR SEMICONDUCTOR EQUIPMENT

(71) Applicant: Taiwan Semiconductor Manufacturing Co., Ltd., Hsinchu (TW)

(72) Inventors: You-Cheng YEH, Hsinchu (TW); Chao-Tzung TSAI, Hsinchu (TW); Jian-Shian LIN, Hsinchu (TW); Hsin-Hui WU, Hsinchu (TW); Mao-Chih HUANG, Hsinchu (TW); Huang-Chang CHEN, Hsinchu (TW); Che-Wei LEE, Hsinchu (TW); Ting Wei LIU, Hsinchu (TW)

(21) Appl. No.: 18/778,716

(22) Filed: Jul. 19, 2024

(51) Int. Cl. H01L 21/67

(52) U.S. Cl. CPC H01L 21/67276

(57) ABSTRACT

A semiconductor equipment calibration system includes a remote calibration system and a calibration apparatus. The cloud-based remote calibration system includes a process tool calibration database storing tool calibration data for a large number of semiconductor process tools. The calibration apparatus is configured to be deployed adjacent to a semiconductor process tool and to receive, from the cloud-based remote calibration system, tool calibration data associated with the semiconductor process tool. The calibration apparatus includes a sensor support arm, a sensor coupled to the sensor support arm and configured to generate sensor data indicating a configuration of a semiconductor process tool, and a control circuit configured to generate diagnostic data by comparing the sensor data to the tool calibration data.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block a semiconductor equipment calibration system, in accordance with some embodiments.

FIG. 2 is a block diagram of a calibration apparatus, in accordance with some embodiments.

FIG. 3 is a block diagram of a remote calibration system 106, in accordance with some embodiments.

FIGS. 4A-4E are illustrations of a calibration apparatus, in accordance with some embodiments.

FIG. 5 is an illustration of a calibration apparatus and process tool, in accordance with some embodiments.

FIGS. 6A-6C are illustrations of a process tool, in accordance with some embodiments.

FIGS. 7 and 8 are illustrations of a calibration apparatus, in accordance with some embodiments.

FIGS. 9A and 9B are illustrations of process tool, in accordance with some embodiments.

FIGS. 10-12 are flow diagrams of methods of calibrating a process tool, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

Embodiments of the disclosure provide a semiconductor equipment calibration system that facilitates efficient and accurate calibration of semiconductor process tools. The system includes a calibration apparatus including one or more sensors and a communication system. When a semiconductor process tool is to be used, the calibration apparatus can be deployed adjacent to the process tool. The calibration apparatus can utilize the one or more sensors to acquire sensor data indicating the positioning or condition of various components of the process tool. The calibration apparatus can compare the sensor data to configuration tool data corresponding to a stored set of parameters indicating proper positions, conditions, or configurations of the process tool. The calibration apparatus can then generate calibration data indicating adjustments or repairs to be performed prior to usage of the process tool.

Accordingly, the process tool can be quickly and efficiently calibrated without the need of manual measurement or human judgment. The result is that the process tool can effectively perform semiconductor processes on wafers without damaging the wafers or damaging the process tool. This avoids expensive repair or replacement of the process tool. This also provides for increased wafer yields and better functioning integrated circuits formed from the wafers. This raises equipment throughput by reducing the time used in parameter calibration. This reduces parameter calibration failure rates. This also benefits in recording the footprint of parameter calibration for yield analysis.

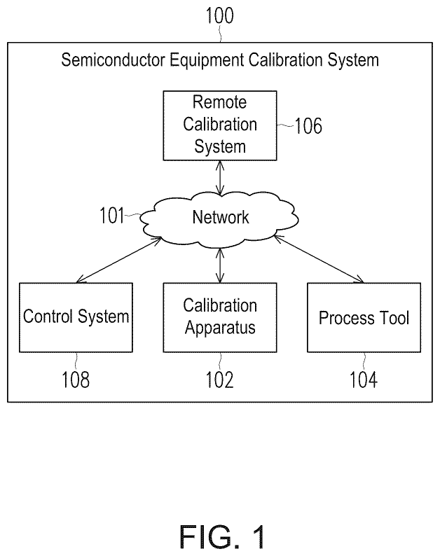

FIG. 1 is a block diagram of a semiconductor equipment calibration system 100, in accordance with some embodiments. The semiconductor equipment calibration system 100 includes a calibration apparatus 102, a remote calibration system 106, and a control system 108. As will be set forth in more detail below, the components of the semiconductor equipment calibration system 100 cooperate to effectively and efficiently calibrate a large variety of process tools 104.

The process tool 104 corresponds to a tool or system that participates in the processing of semiconductor wafers. The process tool 104 can correspond to a tool or system that directly processes the semiconductor wafers. The process tool 104 can correspond to a tool or system that performs one or more functions that assist other process tools in processing the semiconductor wafers. The process tool 104 can include tools or systems dealing with the transport, storage, and monitoring the wafers.

In some embodiments, the process tool 104 includes a thin-film deposition tool. The thin-film deposition tool can include a chemical vapor deposition (CVD) tool that forms thin films on wafers via a CVD process. The thin-film deposition tool can include an atomic layer deposition (ALD) deposition tool that deposits thin films on wafers via an ALD process. The thin-film deposition tool can include a physical vapor deposition (PVD) that deposits thin films on wafers with a physical vapor deposition process.

The thin-film deposition tool can include a thin-film deposition chamber including a wafer carrier or stage surrounded by a chamber wall. The thin-film deposition tool can include fastening devices such as pins or claims that fix the wafer to the mount. The thin-film deposition tool can include electrodes, positioned below, above, or laterally from the wafer. The thin-film deposition tools can include fluid inlets for flowing fluids into the chamber. The thin-film deposition tool can include exhaust channels for flowing fluids out of the chamber. The thin-film deposition tools can include a lid configured to open and close. The thin-film deposition tools can include a wafer receiving port via which wafers can be placed in a retrieved from the chamber.

The positions, conditions, and configurations of the various components of the thin-film deposition tool can affect the deposition processes performed on the wafers. For example, the location of the wafer carrier relative to the chamber wall or shield (i/e, too close, too far, centered, not centered) can affect the quality of thin films formed on the wafers. The position and condition of fastening devices can also affect the quality of thin films formed on the wafers. The relative positions or conditions of electrodes can affect the quality of thin films formed on wafers. The positions or conditions of fluid inlets and exhaust channels can affect the quality of the thin films formed on the wafers. The positions, conditions, and configurations of other aspects of the thin-film deposition tool can affect the deposition performed on wafers.

In some embodiments, the process tool 104 includes an etching tool that etches thin-films or other structures on wafers. The etching tool can include a wet etching tool that performs wet etching processes. The etching tool can include a dry etching tool that performs dry etching processes. The etching tool can include other types of etching tools.

The etching tool can include an etching chamber including a wafer carrier or stage surrounded by a chamber wall. The etching tool can include fastening devices such as pins or claims that fix the wafer to the wafer carrier. The etching tool can include motors that spin or rotate the wafer carrier before, during, or after etching processes. The etching tool can include electrodes, positioned below, above, or laterally from the wafer. The etching tool can include fluid inlets for flowing fluids into the chamber. The etching tool can include exhaust channels for flowing fluids out of the chamber. The etching tool can include a lid configured to open and close. The etching tool can include a wafer receiving port via which wafers can be placed in a retrieved from the chamber.

The positions, conditions, and configurations of the various components of the etching tool can affect the deposition processes performed on the wafers. For example, the location of the wafer carrier relative to the chamber wall or shield (i/e, too close, too far, centered, not centered) can affect the quality of thin films formed on the wafers. The position and condition of fastening devices can also affect the quality of thin films formed on the wafers. The relative positions or conditions of electrodes can affect the quality of thin films formed on wafers. The positions or conditions of fluid inlets and exhaust channels can affect the quality of the thin films formed on the wafers. The positions, conditions, and configurations of other aspects of the etching tool can affect the deposition performed on wafers.

In some embodiments, the process tool 104 includes a photolithography system. The photolithography system can include an immersion lithography system. The immersion lithography system can include a projection lens and an immersion hood coupled to the projection lens. The immersion hood fills with water (or another suitable liquid) and rests on the wafer during the photolithography process. Photolithography light is focused by the projection lens onto the immersion hood. The water in the immersion hood performs a further lensing function to focus the photolithography light onto the wafer. Factors that can affect the quality of the immersion lithography system include the position and occlusion of the liquid inlet and liquid outlet of the immersion hood. Furthermore, the presence of debris at the inlets or in the immersion hood can result in poor function of the immersion photolithography system.

In some embodiments, the photolithography system can include an extreme ultraviolet (EUV) radiation photolithography system that generates EUV radiation. The EUV radiation system can include an EUV radiation generator that includes a collector mirror, one or more lasers, a droplet generator, a droplet receiver, and other components. The positions, conditions, or configurations of these components can affect the quality of EUV radiation generated by the EUV radiation generator. Furthermore, the EUV photolithography system can include a scanner that receives EUV radiation from the EUV generator and directs the EUV radiation onto an EUV reticle includes a mask pattern. Light and reflection the EUV reticle and is directed onto a wafer. The scanner can include a complex arrangement of lenses and mirrors and other optical devices for directing and focusing the EUV radiation. The condition, position, and configuration of the use optical components can affect the quality of the photolithography process.

In some embodiments, the process tool 104 is a device or system associated with the transport or storage of wafers. For example, the process tool 104 can include a front opening unified pod (FOUP). The FOUP can include a plurality of storage slots each configured to hold a wafer during transport. The FOUP can also include a front lid or door configured to securely fasten to the FOUP case during storage or transport. The position, condition, and configuration of the components of the FOUP can help ensure storage and transport of wafers without damaging them. However, any defects in the position, condition, and configuration of the components of the FOUP could result in damage to wafers.

In some embodiments, the process tool 104 includes a wafer loading or unloading robot. The wafer loading or unloading robot can retrieve wafers from a FOUP and load them into another process tool. The wafer loading or unloading robot can retrieve wafers from a FOUP and load them into a secure storage bin. The wafer loading or unloading robot can retrieve wafers from a tool or storage bin and load them into a FOUP. The robot can include a carrying fork or other surface or device that directly contacts a bottom surface of a wafer during loading or unloading. The robot can include one or more arms or arm components. The position, condition, and configuration of the components of the robot arm can contribute to the safe loading and unloading of wafers.

While some examples of the process tools 104 have been provided above, other process tools 104 can be utilized in conjunction with the semiconductor equipment calibration system 100 without departing from the scope of the present disclosure.

In some embodiments, the semiconductor equipment calibration system 100 utilizes the calibration apparatus 102 and the remote calibration system 106 to measure and calibrate the process tool 104 prior to use. The calibration apparatus 102 is a device or system that can be deployed in physical proximity to the process tool 104 in order to sense aspects of the process tool 104 in order to determine whether the process tool 104 is properly arranged are calibrated and is ready for use.

In some embodiments, calibration apparatus 102 includes members that enable stably placing the calibration apparatus 102 adjacent to the process tool 104. For example, the members can include adjustable legs that can be lengthened or shortened to adjust the height or position of other aspects of the calibration apparatus 102. The calibration apparatus 102 can include feet or other members that physically contact the ground or surface adjacent to the process tool 104.

In some embodiments, the calibration apparatus includes sensor supports. The sensor supports can be utilized to support sensors (described further below) of the calibration apparatus. The sensor supports can be adjustable in order to place the sensors in position to accurately and efficiently sense parameters associated with the process tool 104.

In some embodiments, the calibration apparatus 102 includes one or more sensors. The one or more sensors can be coupled to the sensor supports, as described previously. The sensors can include one or more visible light cameras, infrared cameras, ultraviolet cameras or other types of image capture devices. The image capture devices can include charge coupled devices or other types of cameras. The image capture devices can take pictures of various components of the process tool 104 in order to determine positions, conditions, or configurations of components of the process tool 104.

The sensors can include one or more lasers and corresponding laser sensors. The laser scan irradiate various surfaces or components of the process tool 104. The laser sensors can sense laser light reflected from the various surfaces or components of the process tool 104. The sensors can include lidar sensors or other types of sensors. The sensors can include a time-of-flight sensor.

The sensors generate sensor signals. The sensor signals can correspond to analog signals indicative of positions, arrangements, conditions, or other aspects of the process tool 104. The calibration apparatus can include one or more control circuits that process the sensor signals and generate sensor data. The sensor data can correspond to digital representations of the sensor signals. Accordingly, the sensor data is indicative of positions, arrangements, conditions, or other aspects of the process tool 104.

In some embodiments, each sensor includes digital signal processing circuitry that generates digital sensor data from analog sensor signals. The digital signal processing circuitry can include analog-to-digital converters, analog filters, digital filters, or other signal conditioning circuitry that can sensor data that can later be analyzed.

In some embodiments, the sensors are arranged as groups of sensors. Each group of sensors can include one or more of a visible light image capture device, an infrared image capture device, and ultraviolet image capture device, a lidar system, a laser sensing system, or other types of sensors. Each group of sensors can include a control circuit that processes sensor data from the sensors of the group. The control circuit of each group can output sensor the sensor data.

In some embodiments, the calibration apparatus 102 includes a primary control circuit. The primary control circuit may receive sensor signals or sensor data from the various sensors or groups of sensors. Accordingly, the primary control circuit is coupled to sensors or groups of sensors by wired connection or by wireless connection. The primary control circuit can generate overall sensor data for analysis. Further details regarding the primary control circuit are described below.

In some embodiments, the calibration apparatus 102 includes one or more memories. The one or more memories can store parameter data associated with the process tool 104. When the calibration apparatus 102 is deployed to sense the configuration of the process tool 104, the calibration apparatus 102 may receive parameter data associated with the process tool. The parameter data 104 can indicate the proper positions, arrangements, and conditions of components of the process tool 104. For example, the parameter data can indicate the expected distance between a wafer carrier and the interior surface of the process chamber or a shield deployed within the process chamber. The parameter data can indicate the expected positions of electrodes, wafer fastening devices, fluid inlets, fluid outlets, fluid chambers, lid positioning, FOUP tray parameters, or other parameters associated with a particular process tool 104. The parameter data can include expected widths, gaps, surface features, acceptable deterioration parameters, or other aspects of a process tool 104.

In some embodiments, the calibration apparatus 102 receives tool calibration data from the remote calibration system 106 via the one or more networks 101. For example, when the calibration apparatus 102 is deployed, the calibration apparatus 102 can request information regarding the particular type and model of the process tool 104. The calibration apparatus 102 can receive such information from a technician. In some embodiments, the calibration apparatus 102 can read an identification marking on the process tool 104 in order to automatically determine the type and model of the process tool 104. When the calibration apparatus 102 knows the type and model of the process tool 104, the calibration apparatus 102 can make an information request to the remote calibration system 106. The information request can include data indicating the type and model of the process tool 104. The remote calibration system 106 can then provide parameter data or tool calibration data to the calibration apparatus 102. The calibration apparatus 102 can then store the parameter data or tool calibration data associated with process tool 104.

In some embodiments, the control circuit of the calibration apparatus 102 can compare the sensor data to the tool calibration data in order to determine whether or not the process tool 104 is properly calibrated. In some embodiments, the calibration apparatus 102 checks to determine whether the values of the various sensor data fall within acceptable ranges referenced in the tool calibration data. If the sensor data fall within acceptable ranges, then the calibration apparatus 102 can indicate that the process tool 104 is ready for use. If the sensor data does not fall within acceptable ranges, the calibration apparatus 102 can indicate that one or more aspects of the process tool 104 call for further calibration prior to use of the process tool 104. The calibration apparatus 102 can indicate that aspects of the process tool 104 should be calibrated or adjusted prior to use of the process tool 104.

In some embodiments, the calibration apparatus 102 includes a display. The display can display data or other indications or messages. For example, the display can indicate whether the process tool 104 is properly calibrated and ready for use based on the sensor data. The display can indicate whether calibration or adjustment of the process tool 104 should be performed based on the sensor data. The display can also display data indicating the type or model of the process tool 104. The display can indicate whether the sensor data is currently being obtained and whether analysis is currently being performed by the calibration apparatus 102. The display can indicate which aspects of the process tool 104 should be adjusted, as well as the specific parameters of the adjustment should be made.

In some embodiments, the calibration apparatus 102 provides the data to a local control system 108 via the one or more networks 101. In some embodiments, after the control circuit of the calibration apparatus 102 has performed analysis of sensor data, the calibration apparatus 102 can provide diagnostic data to the control system 108. The diagnostic data can indicate whether or not the process tool 104 is ready for use. The diagnostic data can indicate whether or not calibration should be performed on the process tool 104 based on the analysis of the sensor data. The diagnostic data can indicate which aspects of the process tool 104 should be calibrated or adjusted. The diagnostic data can include the specific parameters of adjustments or calibration to be performed.

In some embodiments, the control system 108 is directly coupled to the process tool 104 via the one or more networks 101. The control system 108 can, in some embodiments, calibrate the process tool 104 based on the diagnostic data provided from the calibration apparatus 102. For example, the process tool 104 may include motors or other functionality that enables automated calibration of the process tool 104. In this case, the control system 108 can send control data to the process tool 104 indicating calibrations that should be performed. The process tool can then adjust components based on the control data.

In some embodiments, the control system 108 may control one or more robot arms or other tools to automatically adjust or calibrate the process tool 104 based on the diagnostic data. Accordingly, the control system 108 can output control signals to the robot arms or other tools to adjust or calibrate the process tool 104.

In some embodiments, the control system 108 outputs data to a technician indicating calibration or adjustment but should be performed on the process tool 104. The data can indicate that parameters of adjustments that should be made to the process tool 104. The technician can then manually adjust the process tool 104.

In some embodiments, the control system 108 can control the function of the process tool 104. If the diagnostic data indicates that the process tool 104 should be calibrated or adjusted, then the control system 108 can stop or prevent activation of the process tool 104 until calibration or adjustment has been performed. If the diagnostic data indicates that the process tool is properly calibrated ready for use, then the control system 108 can enable operation of the process tool 104.

In some embodiments, the control system 108 generates the diagnostic data. In this case, the control system 108 can store parameter data or tool calibration data 120 associated with the process tool 104. When the calibration apparatus one to generate sensor data, the sensor data can be provided to the control system 108. The control system 108 can then compare the sensor data to the tool calibration data to determine whether or not the process tool is ready for use or whether calibration or adjustment of the process tool 104 should be performed.

The control system 108 can receive tool calibration data from the remote calibration system 106. Accordingly, the control system 108 is communicatively coupled to the remote calibration system 106 via the one or more networks 101. The control system 108 can request tool calibration data or parameter data from the remote calibration system 106. The control system 108 can provide the type and model of the process tool 104 to the remote calibration system 106 as part of an information request from the control system 108.

In some embodiments, the control system 108 includes processing resources, memory resources, and communication resources. The processing resources can include one or more processors. The memory resources can include one or more memories that store sensor data, tool calibration data, and software associated with operation of the control system 108. The communication resources can include one or more wired or wireless transceivers that can transmit and receive data via one or both of wireless and wired connections.

In some embodiments, the remote calibration system 106 generates the diagnostic data associated with the process tool 104. The calibration apparatus 102 can generate sensor data as described previously. The calibration apparatus 102 can then provide the sensor data to the remote calibration system 106 via the one or more networks 101. The calibration apparatus 102 can also provide the type and model of the process tool 104. The remote calibration system 106 can store tool calibration data or parameter data associated with the process tool 104. The remote calibration system 106 can generate the diagnostic data by comparing the sensor data to the storage tool calibration data 120.

After the remote calibration system 106 generates the diagnostic data, the remote calibration system 106 can provide the diagnostic data or associated commands to the calibration apparatus 102 or to the control system 108. The diagnostic data can indicate whether the process tool 104 is properly calibrated and ready for use. The diagnostic data can indicate whether or not calibration or adjustment should be performed on the process tool 104.

The remote calibration system 106 can correspond to a cloud-based calibration system. Whereas the control system 108, the calibration apparatus 102, and the process tool 104 may be located at a semiconductor fabrication facility, the remote calibration system 106 may be implemented in a cloud-based system. Alternatively, the remote calibration system 106 can also be implemented at the semiconductor fabrication facility. In some embodiments, the remote calibration system 106 is a dispersed system with processing resources, memory resources, and communication resources in dispersed locations.

In some embodiments, diagnostic data may be provided to a mobile electronic device such as a mobile phone, a tablet, a laptop computer, or other types of mobile electronic devices. A technician operating a mobile electronic device can then see the diagnostic data displayed on the mobile electronic device. The technician can then perform calibration of the process tool if the diagnostic data indicates that calibration should be performed. The diagnostic data can be provided to the mobile electronic device via the one or more networks 101. The diagnostic data can be provided to the mobile electronic device from the calibration apparatus 102, the remote calibration system 106, or the control system 108. In some embodiments, the mobile electronic device can store the tool calibration data and can receive sensor data from the calibration apparatus 102. The mobile electronic device can then generate the diagnostic data based on the sensor data and the tool calibration data.

In some embodiments, calibration is performed in iterations. After diagnostic data is generated by one or more of the calibration apparatus 102, the control system 108, and the remote calibration system 106 as described previously, an initial calibration process can be performed based on the diagnostic data. The calibration apparatus 102 can then generate sensor data and diagnostic data can be generated in a second iteration. Further calibration or adjustment can then be performed based on the diagnostic data. Iterations of generating sensor data, diagnostic data, and performing calibration can continue until the diagnostic data indicates that the process tool 104 is ready for use.

In some embodiments, the network 101 can include one or more wireless networks. The network 101 can include one or more wired networks. The network 101 can include the Internet, one or more intranets, or other types of networks.

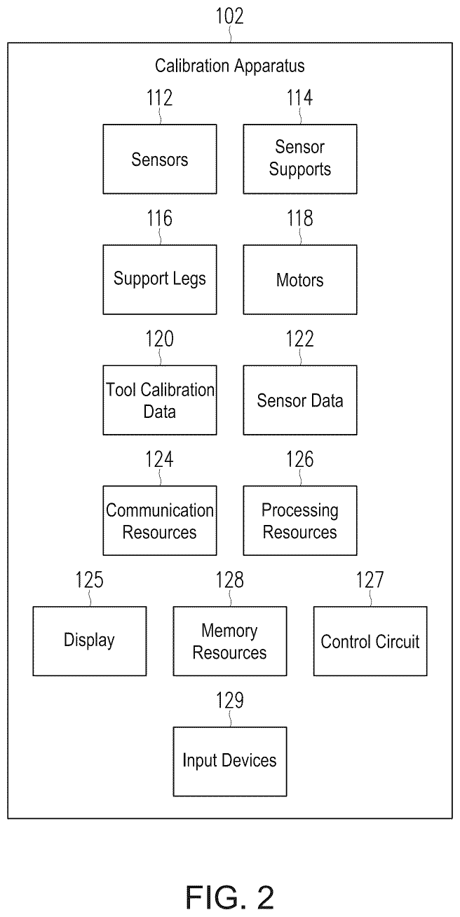

FIG. 2 is a block diagram of the calibration apparatus 102, in accordance with some embodiments. The calibration apparatus 102 of FIG. 2 is one example of the calibration apparatus 102 of FIG. 1. The calibration apparatus 102 includes a plurality of sensors 112 and a plurality of sensors supports 114 as described in relation to FIG. 1. One or more sensors 112 can be coupled to or mounted to each of the sensors supports 114 as described in relation to FIG. 1.

In some embodiments, the calibration apparatus 102 includes a plurality of support legs 116. The plurality of support legs 116 enable the calibration apparatus 102 to be stably deployed adjacent to or even within a process tool 104.

In some embodiments, the calibration apparatus 102 includes a plurality of motors 118. In this case, the support legs 116 and the sensor supports 114 may be adjustable. For example, the support legs and sensors supports 114 may telescope, rotate, bend at joints, or move in other ways. The motors 118 can facilitate movement of the support legs 116 on the sensor supports 114. The motors 118 can correspond to servos, motivator units, or other types of motors or devices that can cause movement of the support legs 116, the sensor supports 114, or other components of the calibration apparatus 102.

The sensors 112 generate sensor data 122. The sensors 112 can generate sensor data by first generating analog sensor signals as described previously. The sensors 112, or control circuitry associated with the sensors 112, can then generate sensor data by processing or conditioning the sensor signals.

The calibration apparatus 102 includes communication resources 124. The communication resources 124 can include one or more wireless transceivers, wired transceivers, or other types of devices or systems that enable the calibration apparatus 102 to transmit and receive data. The communication resources 124 can output sensor data, diagnostic data, process tool model data, request data, or other types of data. The communication resources 124 can receive tool calibration data 120 or parameter data, software instructions, commands, or other types of data.

The calibration apparatus 102 includes processing resources. The processing resources can include one or more microprocessors, one or more microcontrollers, or other types of processing devices. The processing resources can execute software instructions and can control various aspects of the calibration apparatus 102.

The calibration apparatus 102 includes memory resources 128. The memory resources 128 can include one or more computer memories. The one or more computer memories can include read-only memories (ROM), random access memories (RAM), electrically erasable or programmable memories (EEPROM), or other types of memories. The memory resources can store software instructions, tool calibration data 120, sensor data 122, diagnostic data, or other types of data.

The calibration apparatus one includes a control circuit 127. The control circuit 127 can be implemented via the processing resources 126, the memory resources 128, and the communication resources 124. The control circuit 127 can perform the functions described for a control circuit of the calibration apparatus 102 as described in relation to FIG. 1. The control circuit 127 may correspond to a plurality of control circuits. For example, a separate control circuit 127 may be utilized for each sensor 112 or groups of sensors 112.

The calibration apparatus 102 can store tool calibration data 120 for a large number of process tools 104. The tool calibration data 120 can indicate acceptable ranges for a plurality of parameters of the process tool 104. The parameters can include distances, configurations, conditions, or other aspects of the process tool 104 or components of the process tool 104.

In some embodiments, the calibration apparatus 102 includes a display 125. The display 125 can include a screen such as a liquid crystal display (LCD) or other type of display that can display data or graphics associated with operation of the calibration apparatus 102 as described in relation to FIG. 1. The display 125 can include one or more LED indicators. The LED indicators can indicate that sensing or analysis has been performed, that the process tool 104 is ready for use, or that the process tool 104 should be calibrated. Other types of displays can be utilized without departing from the scope of the present disclosure.

In some embodiments, the calibration apparatus 102 can include input devices 129. The input devices can include buttons, toggles, sliders, a touchscreen, switches, a keyboard, or other devices or components that enable a technician to control aspects of the calibration apparatus 102. For example, a technician can utilize the input devices 129 to turn on the calibration apparatus 102, to initiate a diagnostic process, to enter data associated with the process tool 104, or to control other aspects of the calibration apparatus 102.

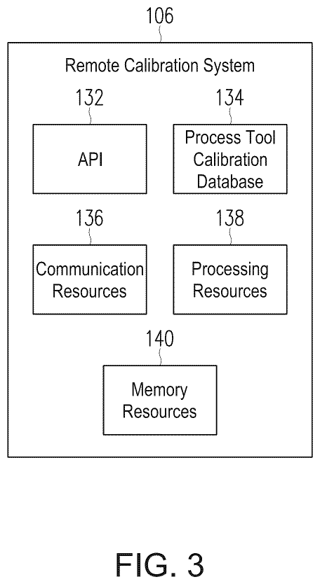

FIG. 3 is a block diagram of a remote calibration system 106, in accordance with some embodiments. The remote calibration system 106 of FIG. 3 is one example of a remote calibration system 106 of FIG. 1. The remote calibration system 106 includes an application programming interface 132. The application programming interface enables the calibration apparatus 102, the control system 108, a mobile electronic device, or other types of devices to interface with remote calibration system 106. The application programming interface 132 enables the remote calibration system 106 to receive request data, sensor data, process tool calibration data, or other types of data. The application programming interface 132 also enables the remote calibration system 106 to provide data such as diagnostic data, calibration commands, tool calibration data, or other types of data to the calibration apparatus 102, the control system 108, a mobile electronic device, or other types of devices. The application programming interface 132 can be accessed via the one or more networks 101 described in relation to FIG. 1.

In some embodiments, the remote calibration system 106 includes a process tool calibration database. The process tool calibration database can store tool calibration data associated with a large number of process tools 104. The remote calibration system 106 can periodically update the process tool calibration database 134 with new tool calibration data.

In some embodiments, the remote calibration system 106 includes communication resources 136. The communication resources 136 can include one or more wireless transceivers or wired transceivers that enable the reception and transmission of data.

In some embodiments, the remote calibration system 106 includes processing resources 138. The processing resources can include one or more microprocessors, microcontrollers, virtual processors, or other types of processors. The processors can control aspects of the remote calibration system 106 and can execute software instructions.

In some embodiments, the remote calibration system 106 can include memory resources 140. The memory resources 140 can include one or more computer memories. The process tool calibration database 134 can be implemented in conjunction with the memory resources 140. The communication resources 136, the processing resources 138, and the memory resources 140 can be utilized to perform the functions of the remote calibration system one described in relation to FIGS. 1 and 2.

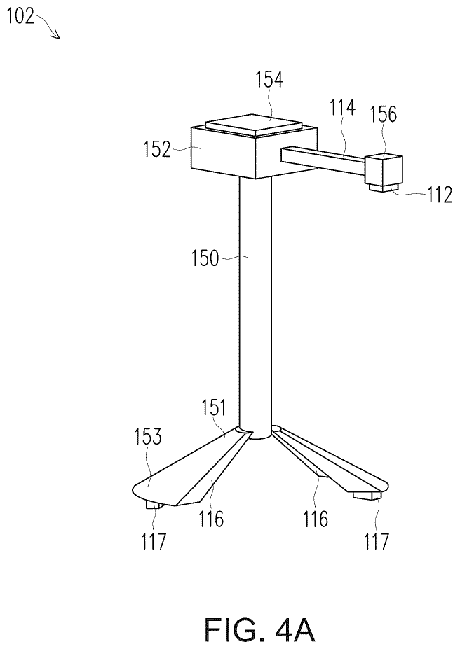

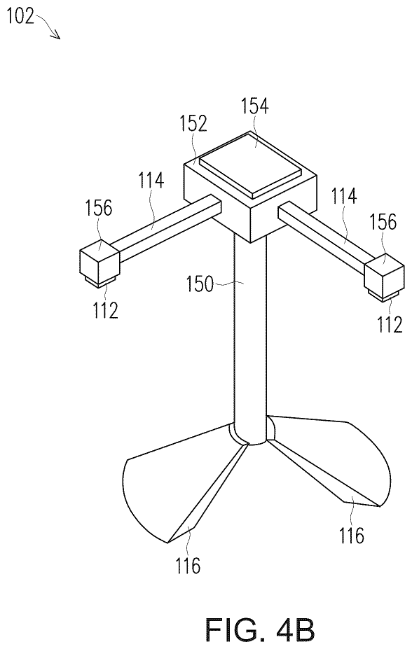

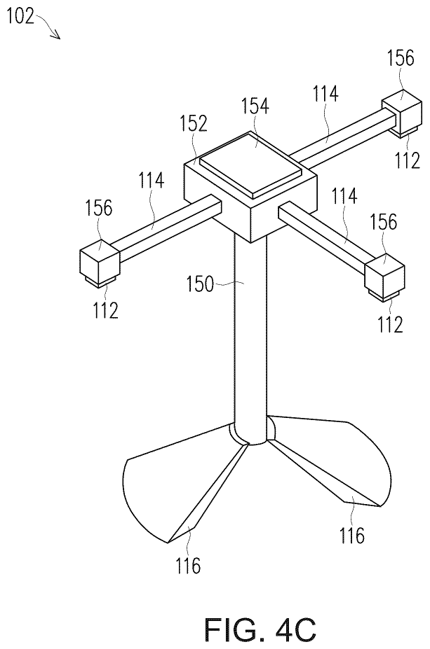

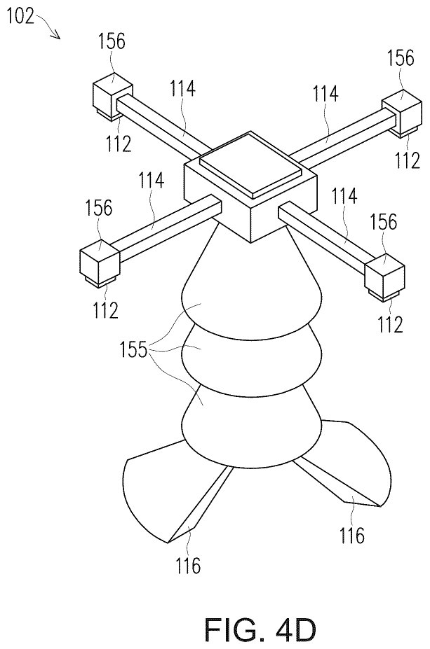

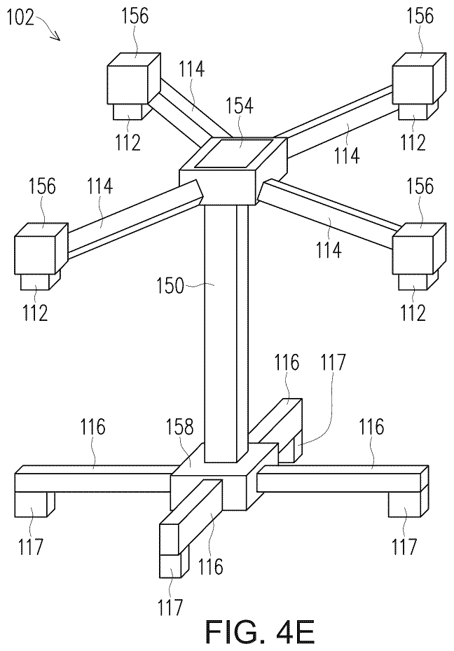

FIG. 4A is an illustration of the calibration apparatus 102, in accordance with some embodiments. The calibration apparatus 102 is one example of a calibration apparatus 102 of FIGS. 1 and 2.

The calibration apparatus 102 includes support legs 116 coupled to a calibration support column 150. Each support leg 116 includes a coupling end 151 that is coupled to the base of the calibration support column 150. Each support leg 116 includes a base end 153. The support leg 116 includes a fan shape and that the coupling end 151 is narrower than the base end 153. This can help provide stability to the calibration apparatus 102.

The calibration apparatus 102 includes a foot 117 coupled to each support leg 116. In particular, the foot 117 is coupled to the base and 153 of the support leg 116. The length of the support legs can be extended or retracted in an automatic or manual adjustment mode. The automatic adjustment mode, a motor (not shown) can extend or retract the support legs 116. The foot 117 can also have an adjustable installation position with varying height levels.

While FIG. 4A illustrates two support legs 116, in practice, the calibration apparatus 102 can include additional support legs 116. Furthermore, the calibration apparatus 102 can include other shapes and configurations of support legs 116. As described previously, in some embodiments, the support legs 116 are adjustable.

In some embodiments, the support column 150 is adjustable. The support column 150 can telescope in order to increase the height or decrease the height of the support column 150. This has the effect of increasing or decreasing the height of the calibration apparatus 102. The support column 150 can include various types of length adjustable mechanisms. Though not shown, the support column 150 can include light markings to indicate the current extension or height of the support column 150. The support column 150 can include an optical ruler. The vertical length can be adjusted and then fixed in place. The vertical length of the support column 150 can be adjusted in an automatic mode or in manual mode. In the automatic mode a motor (not shown) can adjust the vertical length. In some embodiments, the support legs 116 and the support column 150 can result in a total adjustable height between 300 mm and 450 mm, though other dimensions can be utilized without departing from the scope of the present disclosure.

In some embodiments, the calibration apparatus 102 includes a main body bracket 152. The main body bracket is mounted atop the support column 150. The main body bracket 152 can house communication resources 124, processing resources 126, memory resources 128, and other electronic components of the calibration apparatus 102. The main body bracket 152 can rotate vertically 360° and can be adjusted in an automatic mode or a manual mode. In the automatic mode, a motor (not shown) can rotate the main body bracket 152.

In some embodiments, a control panel 154 is mounted on the main body bracket 152. The control panel 154 can include a display 125, input devices 129, or other components. A technician can control aspects of the calibration apparatus 102, can input commands or data to the calibration apparatus 102, and can receive or view data via the control panel 154. The control panel can include a position reading and control for each actual direction and an automated mode. The control panel 154 can facilitate inputting parameter settings.

In some embodiments, the calibration apparatus 102 includes a sensor support 114 coupled to the main body bracket 152. The sensor support 114 extends laterally from the main body bracket 152. As described previously, the sensor support 114 can telescope or otherwise adjust the length. The sensor support 114 can be rotated in a manual mode or in automatic mode. In the automatic mode, a motor (not shown) adjusts the sensor support 114. In some embodiments, the adjustable length of the sensor support 114 is between 250 and 350 mm. Other shapes, configurations, and ranges can be utilized for the sensor support 114 without departing from the scope of the present disclosure.

In some embodiments, the calibration apparatus 102 includes a sensor bracket 156 coupled to the end of the sensor support 114. One or more sensors 112 are mounted to the sensor support bracket 156. As described previously, a group of sensors 112 may be mounted to the sensor support bracket 156. Sensor circuitry may be housed within the sensor support bracket 156. The s sensor support bracket 156 can rotate horizontally 360°, can be adapted for different sensor locks, and can include an automatic or a manual adjustment mode. In the automatic adjustment mode, a motor can rotate the sensor bracket 156.

In some embodiments, the support posts 150, the support legs 116, the main bracket 152, the sensor support 114, and the sensor bracket 156 are made from a same material. In one example, the material is aluminum alloy. However, other metal, plastic, or ceramic materials can be utilized for components of the calibration apparatus 102 without departing from the scope of the present disclosure.

FIG. 4B is an illustration of a calibration apparatus 102, in accordance with some embodiments. The calibration apparatus 102 of FIG. 4B is one example of a calibration apparatus 102 of FIGS. 1 and 2. The calibration apparatus 102 of FIG. 4B is substantially similar to the calibration apparatus 102 of FIG. 4A, except that the calibration apparatus 112 of FIG. 4B includes two sensor supports 114 and two corresponding sensor brackets 156 and sensors 112. The sensor supports 114 extend substantially perpendicularly to each other in lateral directions. As described previously, each sensor 112 can correspond to a group of sensors 112.

FIG. 4C is an illustration of a calibration apparatus 102, in accordance with some embodiments. The calibration apparatus 102 of FIG. 4C is one example of a calibration apparatus 102 of FIGS. 1 and 2. The calibration apparatus 102 of FIG. 4C is substantially similar to the calibration apparatus 102 of FIG. 4A, except that the calibration apparatus 112 of FIG. 4C includes three sensor supports 114 and three corresponding sensor brackets 156 and sensors 112.

FIG. 4D is an illustration of a calibration apparatus 102, in accordance with some embodiments. The calibration apparatus 102 of FIG. 4D is one example of a calibration apparatus 102 of FIGS. 1 and 2. The calibration apparatus 102 of FIG. 4D is substantially similar to the calibration apparatus 102 of FIG. 4A, except that the calibration apparatus 112 of FIG. 4D includes four sensor supports 114 and four corresponding sensor brackets 156 and sensors 112. Furthermore, the calibration apparatus 102 of FIG. 4D includes three central support members 155 rather than a single support posts 150. The central support members 155 are shaped as concentric frustums. The central support members 155 may be coupled around a post central support member.

FIG. 4E is an illustration of a calibration apparatus 102, in accordance with some embodiments. The calibration apparatus 102 of FIG. 4E is one example of a calibration apparatus 102 of FIGS. 1 and 2. The calibration apparatus 102 of FIG. 4E is similar to the calibration apparatus 102 of FIG. 4A in many regards. Some differences include a central support 150 having a rectangular cross-section rather than circular cross-section, and a base bracket 158 coupled to a bottom of the central support 150. Furthermore, for support legs 116 each other rectangular cross-section and extends substantially laterally outward from the base bracket 158. A foot 117 is coupled to each support leg 116. The calibration apparatus 112 of FIG. 4E includes four sensor supports 114 and four corresponding sensor brackets 156 and sensors 112. Other configurations of a calibration apparatus 102 can be utilized without departing from the scope of the present disclosure.

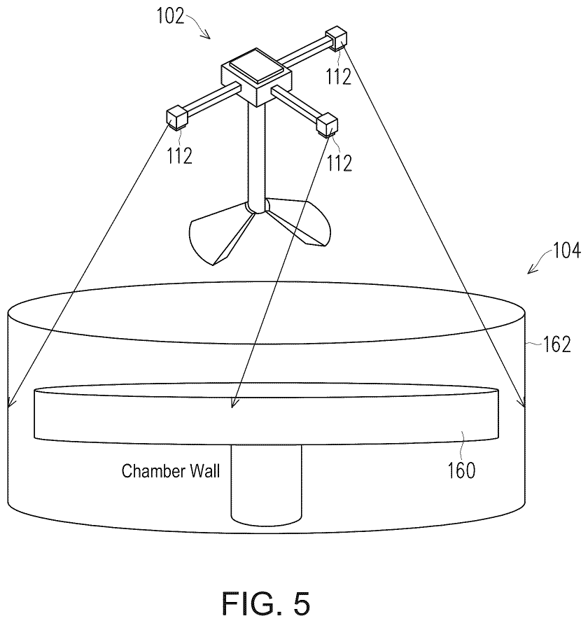

FIG. 5 is an illustration of a calibration apparatus 102 deployed to measure an aspect of a process tool 104, in accordance with some embodiments. The process tool 104 includes a wafer carrier 160 configured to hold a wafer during a semiconductor process. The process tool can correspond to a thin-film deposition tools, an etching tool, or other types of process tools.

Prior to using the process tool 104, the calibration apparatus 102 is deployed to measure the gap between the edges of the wafer carrier 160 and the chamber wall 162 of the process tool 104. The calibration apparatus 102 is deployed either outside of the process tool and adjacent to the process tool, or within the process tool. The calibration apparatus 102 can be deployed in a manner that enables the three sensors 112 to perform measurements. Each sensor 112 then measures the gap between the edge of the wafer carrier and the interior surface of the chamber wall 162 at three respective positions. The sensor 112 can perform these measurements utilizing the types of sensors described previously. The three measurements in different locations can help determine whether or not the wafer carrier 160 is centered within the chamber wall 162. The sensors 112 can generate sensor data which can then be processed to generate diagnostic data, as described previously. If the diagnostic data calls for adjust or calibration of the position of the wafer carrier 160, then a manual or automated adjustment or calibration process can be performed, as described previously.

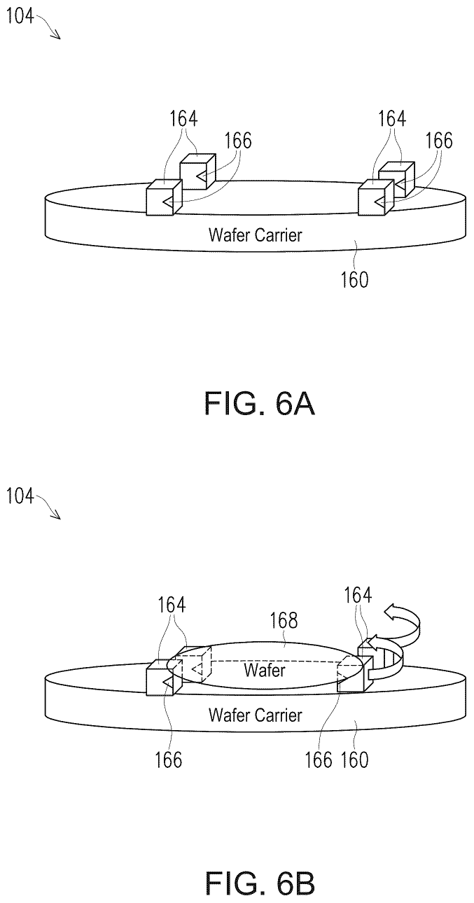

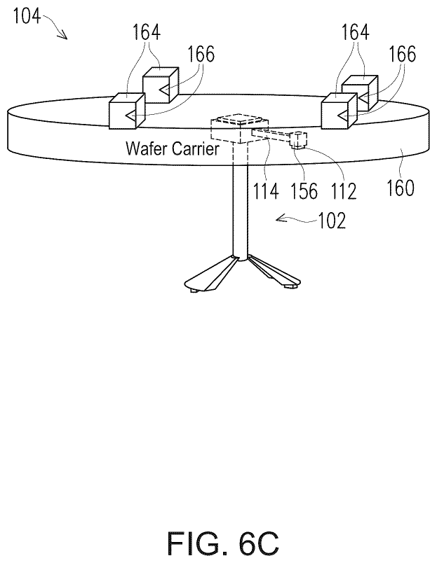

FIGS. 6A-6C illustrate a process tool 104 including a wafer carrier 160 and fastening devices 164, in accordance with some embodiments. Each of the fastening devices 164 is mounted on the surface of the wafer carrier 160. Each passing device includes a gap 166. The gap 166 is configured to receive an edge of the wafer 168. In FIG. 6A, a wafer 168 has not yet been positioned in the fastening devices 164. The fastening devices 164 on the right side are rotated so that the gap faces outward.

In FIG. 6B, a wafer 168 has been placed so that the edge of the wafer 168 is positioned in the gaps 166. The fastening devices on the right are rotated so that the wafer 168 is firmly held. In the example of FIGS. 6A-6C, the process tool 104 is a wet etching tool. In the final step of the wet etching process, a drying operation is performed. During the drying operation, the wafer carrier is rapidly rotated so that fluids are removed from the wafer 168.

After repeated processes, it is possible that the gaps 166 will become worn down such that the wafer 168 is not securely held. The rotation of the wafer in this situation can result in the wafer 168 being severely damaged.

In FIG. 6C, the calibration apparatus 102 has been deployed such that the sensor 112 is positioned laterally from the fastening devices 164. The sensor bracket 156 can be rotated so that the sensor 112 face the fastening devices 164. The sensor 112 can then measure the width of the gap 166. The sensor 112 generates sensor data indicating what to the gap. Diagnostic data can be generated by comparing the sensor data to the acceptable gap width ranges. The diagnostic data can indicate that calibration, adjustment, replacement, or repair of the fastening device 164 should be performed before process tool 104 is used again.

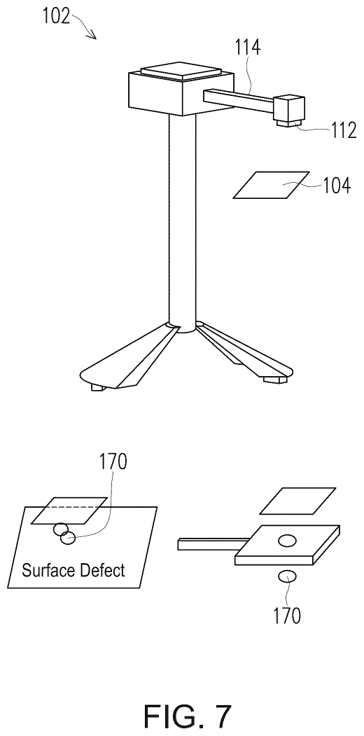

FIG. 7 is an illustration of a calibration apparatus 102, in accordance with some embodiments. The calibration apparatus 102 includes a single sensor support 114 and sensor 112. The calibration apparatus 102 is deployed to image a surface of a component of a process tool 104 in order to identify defects 170. If the sensor data indicates the presence of defects, the diagnostic data can call for calibration, adjustment, or repair of the surface that includes the defects 170.

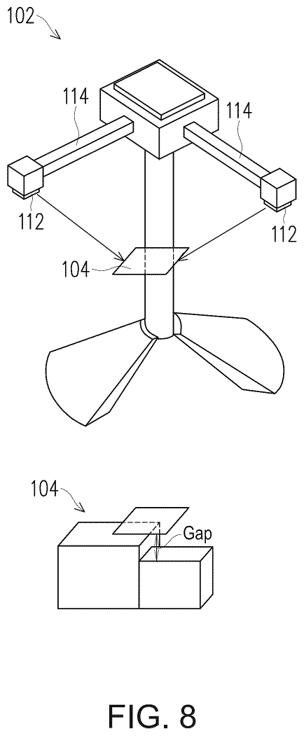

FIG. 8 is an illustration of a calibration apparatus 102, in accordance with some embodiments. The calibration apparatus 102 includes two sensor supports 114 and two sensors 112. The calibration apparatus 102 is deployed to image the vertical gap between two surfaces of the process tool 104. Because two sensors at different angles are utilized, the vertical gap between the two surfaces can be indicated in the sensor data. If the vertical gap can then be compared to calibration data to determine whether or not calibration is needed. In

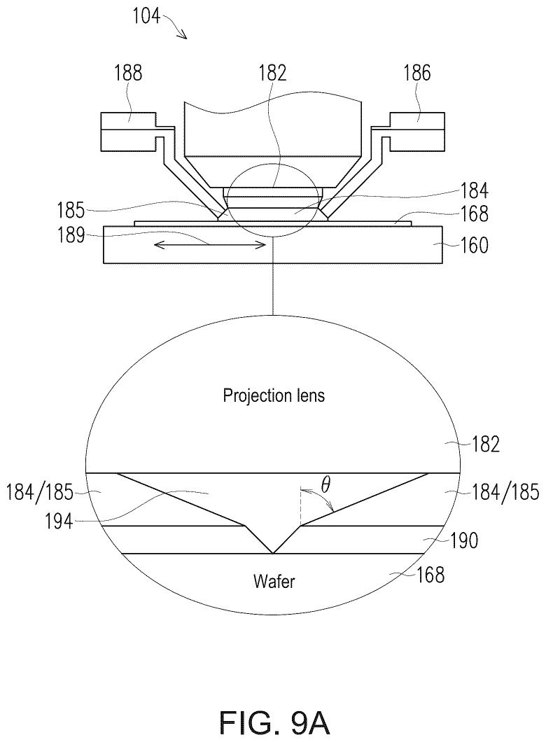

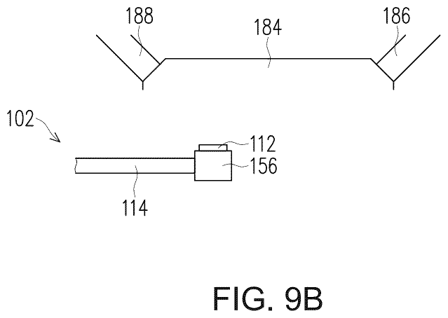

FIG. 9A is an illustration of a process tool 104, in accordance with some embodiments. The process tool 104 of FIG. 9A is an immersion lithography apparatus, as described previously. The immersion lithography apparatus includes a projection lens 182 that outputs photolithography light 194 onto a wafer 168 held by a wafer carrier 160. The immersion lithography apparatus includes an immersion hood 184 filled with water 185 on the surface of a layer of photoresist 190 on the wafer 168. A liquid supply supplies the water 185 into the immersion hood. A liquid recovery recovers the water 185 from the immersion hood. If there are any defects on the interior of the immersion hood 184, then the photolithography process can be ruined in the wafer 168 will not be processed properly.

FIG. 9B is an illustration of the immersion hood 184 and measured by a calibration apparatus 102, in accordance with some embodiments. Prior to usage of the immersion hood 184, the calibration apparatus 102 is deployed in the sensor 112 is rotated to face upward to generate sensor data of the interior of the immersion hood 184. If the sensor data indicates damage, defects, or debris in the interior of the immersion and 184, the diagnostic data can indicate that further calibration, adjustment, or repair is needed. The calibration apparatus 102 in conjunction with the entirety of the semiconductor equipment calibration system 100 enables the efficient and effective diagnosis and calibration of the immersion hood 184.

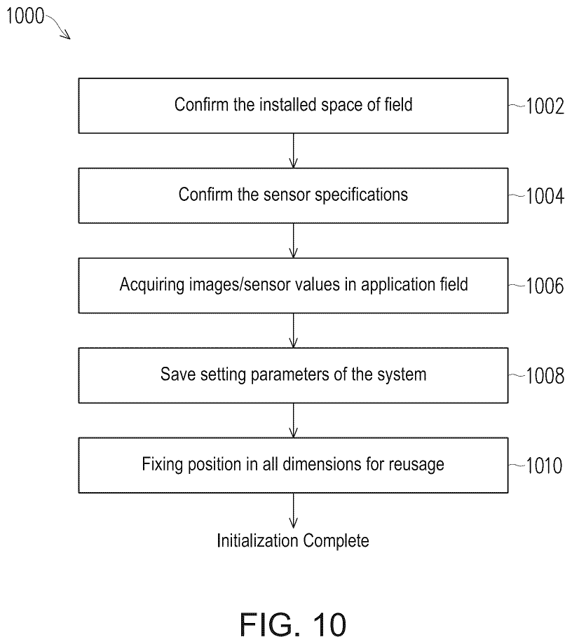

FIG. 10 is a flow diagram of a method 1000 for initializing a calibration system for a process tool, in accordance with some embodiments. The method 1000 can utilize processes, components, and systems described in relation to the foregoing figures. At 1002, the method 1000 includes comparing the installed space of field. At 1004, the method 1000 includes confirming the sensor specifications. At 1006, the method 1000 includes acquiring images and sensor values in an application field. At 1008, the method 1000 includes saving setting parameters of the system. At 1010, the method 1000 includes fixing position in all dimensions for re-usage. Initialization of the calibration system is complete.

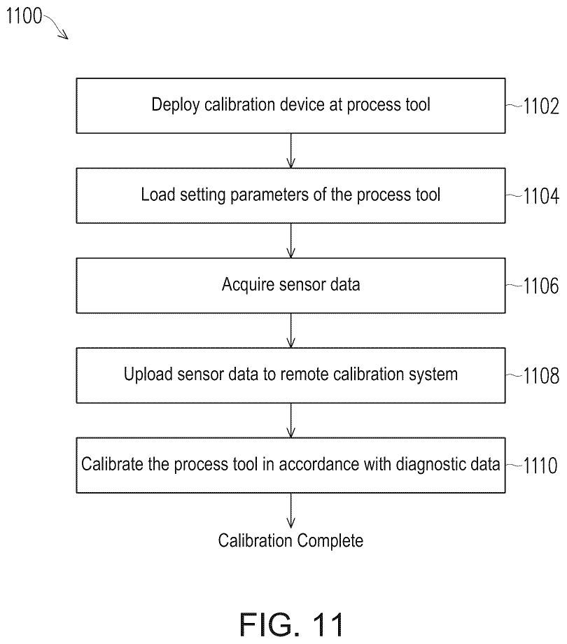

FIG. 11 is a flow diagram of a method 1100 for initializing a calibration system for a process tool, in accordance with some embodiments. The method 1100 can utilize processes, components, and systems described in relation to the foregoing figures. At 1102, the method 1100 includes deploying a calibration device at the process tool. At 1104, the method 1100 includes loading setting parameters of the process tool. At 1106, the method 1100 includes acquiring sensor data. At 1108, the method 1100 includes uploading the sensor data to a remote calibration system. At 1110, the method 1100 includes calibrating the process tool in accordance with diagnostic data.

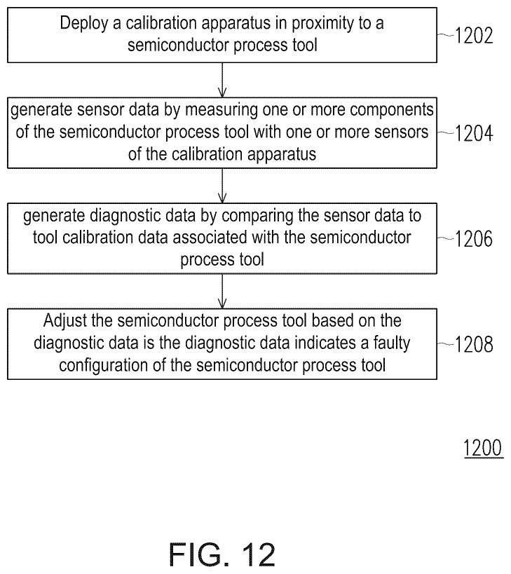

FIG. 12 is a flow diagram of a method 1200, in accordance with some embodiments. The method 1200 can utilize processes, components, and systems described in relation to the foregoing figures. At 1202, the method 1200 includes deploying a calibration apparatus in proximity to a semiconductor process tool. One example of a calibration apparatus is the calibration apparatus 102 of FIG. 1. One example of a semiconductor process tool is the semiconductor process tool 104 of FIG. 1. At 1204, the method 1200 includes generating sensor data by measuring one or more components of the semiconductor process tool with one or more sensors of the calibration apparatus. At 1206, the method 1200 includes generating diagnostic data by comparing the sensor data to tool calibration data associated with the semiconductor process tool. At 1208, the method 1200 includes adjusting the semiconductor process tool based on the diagnostic data if the diagnostic data indicates a faulty configuration of the semiconductor process tool.

In some embodiments, a method includes deploying a calibration apparatus in proximity to a semiconductor process tool and generating sensor data by measuring one or more components of the semiconductor process tool with one or more sensors of the calibration apparatus. The method includes generating diagnostic data by comparing the sensor data to tool calibration data associated with the semiconductor process tool and adjusting the semiconductor process tool based on the diagnostic data if the diagnostic data indicates a faulty configuration of the semiconductor process tool.

In some embodiments, a calibration apparatus includes a support leg, a support column coupled to the support leg, and a first sensor support arm coupled to the support column. The calibration apparatus includes a first sensor coupled to the first sensor support arm and configured to generate sensor data indicating a configuration of a semiconductor process tool and a display configured to output at least a portion of diagnostic data generated based on a comparison of the sensor data to tool calibration data associated with the semiconductor process tool.

In some embodiments, a system includes a cloud-based remote calibration system including a process tool calibration database and a calibration apparatus configured to receive, from the cloud-based remote calibration system, tool calibration data associated with a semiconductor process tool. The calibration apparatus includes a sensor support arm, a sensor coupled to the sensor support arm and configured to generate sensor data indicating a configuration of a semiconductor process tool, and a control circuit configured to generate diagnostic data by comparing the sensor data to the tool calibration data.

Embodiments of the disclosure provide a semiconductor equipment calibration system that facilitates efficient and accurate calibration of semiconductor process tools. The system includes a calibration apparatus including one or more sensors and a communication system. When a semiconductor process tool is to be used, the calibration apparatus can be deployed adjacent to the process tool. The calibration apparatus can utilize the one or more sensors to acquire sensor data indicating the positioning or condition of various components of the process tool. The calibration apparatus can compare the sensor data to configuration tool data corresponding to a stored set of parameters indicating proper positions, conditions, or configurations of the process tool. The calibration apparatus can then generate calibration data indicating adjustments or repairs to be performed prior to usage of the process tool.

Accordingly, the process tool can be quickly and efficiently calibrated without the need of manual measurement or human judgment. The result is that the process tool can effectively perform semiconductor processes on wafers without damaging the wafers or damaging the process tool. This avoids expensive repair or replacement of the process tool. This also provides for increased wafer yields and better functioning integrated circuits formed from the wafers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
deploying a calibration apparatus in proximity to a semiconductor process tool;
generating sensor data by measuring one or more components of the semiconductor process tool with one or more sensors of the calibration apparatus;
generating diagnostic data by comparing the sensor data to tool calibration data associated with the semiconductor process tool; and
adjusting the semiconductor process tool based on the diagnostic data if the diagnostic data indicates a faulty configuration of the semiconductor process tool.

2. The method of claim 1, comprising receiving, with the calibration apparatus, parameter data associated with the semiconductor process tool, wherein deploying the calibration apparatus includes automatically adjusting a length of a sensor support arm of the calibration apparatus based on parameters of the semiconductor process tool.

3. The method of claim 1, comprising:
receiving, from a remote calibration system with the calibration apparatus, the tool calibration data; and
generating the diagnostic data by comparing the sensor data to the tool calibration data with the calibration apparatus.

4. The method of claim 1, comprising:
providing the sensor data from the calibration apparatus to a remote calibration system;
generating the diagnostic data by comparing the sensor data to the tool calibration data with the remote calibration system; and
providing the diagnostic data to the calibration apparatus.

5. The method of claim 1, comprising:
automatically preventing operation of the semiconductor process tool if the diagnostic data indicates a faulty configuration of the semiconductor process tool;
generating new sensor data after adjusting the semiconductor process tool;
generating new diagnostic data by comparing the new sensor data to the tool calibration data; and
enabling operation of the semiconductor process tool if the new diagnostic data indicates that the semiconductor process tool is properly calibrated.

6. The method of claim 1, comprising downloading calibration system software with the calibration apparatus from a remote calibration system prior to generating the sensor data.

7. The method of claim 1, comprising interfacing the calibration apparatus with a remote calibration system via an application programming interface of the remote calibration system.

8. The method of claim 1, comprising displaying a portion of the diagnostic data on a display of the calibration apparatus.

9. The method of claim 1, wherein the sensor data indicates a proximity of a wafer carrier of the semiconductor process tool to a chamber wall of the semiconductor process tool.

10. The method of claim 1, wherein the sensor data indicates surface features of an interior of an immersion hood of the semiconductor process tool.

11. A calibration apparatus, comprising:
a support leg;
a support column coupled to the support leg;
a first sensor support arm coupled to the support column;
a first sensor coupled to the first sensor support arm and configured to generate sensor data indicating a configuration of a semiconductor process tool; and
a display configured to output at least a portion of diagnostic data generated based on a comparison of the sensor data to tool calibration data associated with the semiconductor process tool.

12. The calibration apparatus of claim 11, comprising:
one or more memories configured to store software data of a process tool calibration system; and
one or more processors configured to execute the software instructions to perform a calibration process for the semiconductor process tool.

13. The calibration apparatus of claim 11, wherein the calibration process includes:
generating the sensor data; and
generating the diagnostic data by comparing the sensor data to the tool calibration data.

14. The calibration apparatus of claim 11, comprising a transceiver configured to send and receive data from a remote calibration system.

15. The calibration apparatus of claim 11, wherein the first sensor support arm and the support column have adjustable lengths.

16. The calibration apparatus of claim 15, comprising one or more motors configured to automatically adjust the lengths of the first sensor support arm and the support column.

17. The calibration apparatus of claim 11, comprising
a second sensor support arm coupled to the support column; and
a second sensor coupled to the second sensor support arm.

18. A system, comprising:
a cloud-based remote calibration system including a process tool calibration database; and
a calibration apparatus configured to receive, from the cloud-based remote calibration system, tool calibration data associated with a semiconductor process tool, the calibration apparatus including:
a sensor support arm;
a sensor coupled to the sensor support arm and configured to generate sensor data indicating a configuration of a semiconductor process tool; and
a control circuit configured to generate diagnostic data by comparing the sensor data to the tool calibration data.

19. The system of claim 18, wherein the cloud-based remote calibration system includes an application programming interface configured to enable the calibration apparatus to receive the tool calibration data.

20. The system of claim 19, wherein the sensor is coupled to the support arm by a rotatable bracket.
